(19) United States
(12) Patent Application Publication
(10) Pub. No.: US 2017/0226627 A1
(43) Pub. Date: Aug. 10, 2017

(54) EVAPORATION CRUCIBLE AND EVAPORATION SYSTEM

(71) Applicants: BOE Technology Group Co., Ltd., Beijing (CN); Ordos Yuansheng Optoelectronics Co., Ltd., Inner Mongolia (CN)

(72) Inventors: Long Jin, Beijing (CN); Junjie Huang, Beijing (CN); Wenbin Yang, Beijing (CN); Fuqiang Tang, Beijing (CN)

(21) Appl. No.: 15/501,566

(22) PCT Filed: Mar. 9, 2016
(86) PCT No.: PCT/CN2016/075964

§ 371 Date: Feb. 3, 2017

(30) Foreign Application Priority Data
Sep. 29, 2015 (CN) 201510631940.5

(51) Int. Cl. C23C 14/24; C23C 14/58

(52) U.S. Cl. CPC C23C 14/243; C23C 14/58

(57) ABSTRACT

An evaporation crucible and an evaporation system are disclosed. The evaporation crucible includes a crucible body and at least one nozzle located on a top face of the crucible body. The crucible body includes an inner wall and an outer wall that are bonded together, where the inner wall is formed of a first material, the outer wall is made of a second material, and a heat conductivity of the first material is larger than that of the second material. The evaporation crucible and the evaporation system may solve technical problem of non-uniform evaporation of vapor deposition material in prior arts, such that a uniform coating on OLED substrate may be achieved.

### CROSS REFERENCE TO RELATED APPLICATIONS

This application is a Section 371 National Stage Application of International Application No. PCT/CN2016/075964, filed on 9 Mar. 2016, entitled “EVAPORATION CRUCIBLE AND EVAPORATION SYSTEM”, which claims priority to Chinese Application No. 201510631940.5, filed on 29 Sep. 2015, incorporated herein by reference in its entirety.

### TECHNICAL FIELD

Embodiments of the invention relate to an evaporation crucible and an evaporation system, and specifically to an evaporation crucible and an evaporation system for manufacturing OLED display devices.

### BACKGROUND

Organic light-emitting diode (OLED) display devices, which represent a trend of development of displays of next generation, have become more and more important in current flat display market due to advantages such as thin, low power consumption, high contrast ratio, high color gamut, and being adapted for flexible display.

OLED displays includes passive-matrix organic light-emitting diode (PMOLED) displays and active-matrix organic light-emitting diode (AMOLED) displays, where the AMOLED displays may be realized by a low temperature poly-silicon (LTPS) backplate plus a fine metal mask (FMM), or by an oxide backplate plus a white light OLED (WOLED) plus a color filter (CF). The former is mainly used for small sized panels, such as, mobile phones and mobile applications; the latter is mainly used for large sized panels, such as monitors, TV sets and the like. Currently, the LTPS backplate plus FMM manner has been maturely developed and has been used for mass production.

In the LTPS backplate plus FMM manner, vapor deposition materials for OLED are evaporated in a predetermined sequence to be deposited onto the LTPS backplate, where red, green and blue components are formed through utilizing a pattern on the FMM. Evaporation is performed in a vacuum chamber. In mass production, linear evaporation sources are used, such as linear crucibles. Traditional crucibles are usually made of Titanium (Ti), which has a low heat conductivity, and as the crucible has a hollow structure, it has a bad temperature uniformity across the entire crucible body, such that some vapor deposition materials inside the crucible may not be evaporated while other vapor deposition materials may be overheated and degenerated. Non-uniformity of evaporation may finally lead to unqualified OLED panels.

FIG. 1 is a schematic drawing showing a structure of a prior art evaporation crucible. As shown in FIG. 1, a crucible 100 for performing a vapor deposition on an OLED substrate includes a crucible body 1 and a plurality of nozzle 2 located at a top surface of the crucible body 1, the crucible body may be formed of Ti. A spacing between adjacent nozzles 2 is A. The crucible 100 shown in FIG. 1 may have a substantially rectangular shape, and its side surface and bottom surface are provided with heating pipes 3 for heating organic vapor deposition materials inside the crucible, so as to perform vapor deposition on the OLED substrate.

During evaporating the vapor deposition material by the crucible 100 shown in FIG. 1, the following situation may occur: materials contacting the side wall and the bottom wall of the crucible are evaporated first, while materials in central region of the crucible are evaporated slowly, such that evaporation uniformity of the entire evaporation source is adversely affected. Further, if stability of materials is not very good, then when an evaporation rate of central materials has arrived at a required evaporation rate, the materials contacting the side wall may have already been degenerated, resulting in a waste of material.

### SUMMARY

An object of embodiments of the invention is to provide an evaporation crucible and an evaporation system, which may solve the technical problem of non-uniform evaporation of vapor deposition material in prior arts and may perform a uniform vapor deposition on OLED substrates.

According to an aspect of the invention, there is provided an evaporation crucible, which may comprise: a crucible body; and at least one nozzle located on a top face of the crucible body, where the crucible body comprises an inner wall and an outer wall that are bonded together, the inner wall is formed of a first material, the outer wall is made of a second material, and a heat conductivity of the first material is larger than that of the second material.

According to an embodiment of the invention, the outer wall may be formed of Ti, and the inner wall may be formed of a material selected from a group consisted of Cu, Ag, Al and a combination thereof.

According to an embodiment of the invention, the evaporation crucible comprises one or two nozzles.

According to an embodiment of the invention, the evaporation crucible may further comprise a heating device disposed externally to the crucible body for heating the crucible.

According to another aspect of the invention, there is provided an evaporation system for performing vapor deposition on an objective substrate. The evaporation system may comprise a plurality of crucibles arranged into a certain pattern, and each crucible may be the evaporation crucible according to any one of the above embodiments.

According to an embodiment of the invention, the plurality of crucibles may be arranged such that spacings between any two adjacent nozzles are the same.

According to an embodiment of the invention, the plurality of crucibles may be arranged into a linear evaporation source.

According to an embodiment of the invention, the plurality of crucibles may be arranged into an area evaporation source.

According to an embodiment of the invention, the evaporation system may further comprise a plurality of crucible moving device for moving the plurality of crucibles respectively and independently.

According to an embodiment of the invention, each crucible moving device may comprise a guiding rail and a servo motor for driving a corresponding crucible to move on the guiding rail.

According to an embodiment of the invention, each crucible may be provided with a heating device.

According to an embodiment of the invention, each crucible may be provided with a separating device for controlling a corresponding heating device to move close to or away from the crucible.

According to an embodiment of the invention, each crucible may be provided with a temperature detecting device for measuring a temperature of the crucible.

According to an embodiment of the invention, the evaporation system may further comprise a control device associated with the moving device, the heating device, the separating device and the temperature detecting device, for controlling operations of the moving device, the heating device, the separating device and the temperature detecting device.

In the evaporation crucible according to the embodiment of the invention, the crucible body comprises an inner wall and an outer wall that are bonded together, the inner wall is formed of a first material, the outer wall is made of a second material, and a heat conductivity of the first material is larger than that of the second material. Therefore, when the crucible is heated, heat may quickly transferred through the material of the inner wall, such that temperature across the inner wall which contacts vapor deposition material can be uniformized, and the vapor deposition material may be uniformly heated and evaporated, and thereby a uniform coating can be obtained.

According to the evaporation system disclosed in the embodiment of the invention, a plurality of small crucibles may form an evaporation system to replace a large sized crucible in prior arts, such that a technical problem that vapor deposition material at central region inside the large sized crucible cannot be sufficiently heated to provide a sufficient evaporation can be avoided, and uniformity of coating may be improved.

Objectives, features and advantages of the embodiment of the invention may be more apparent with the embodiments described hereinafter in conjunction with the appended drawings.

### BRIEF DESCRIPTION OF THE DRAWINGS

FIG. 1 is a schematic drawing showing a structure of a prior art evaporation crucible.

FIG. 2 is a schematic drawing showing a structure of an evaporation system including a plurality of crucibles according to an embodiment of the present application.

FIG. 3a is a schematic plan view showing an evaporation crucible forming a spot evaporation source according to an embodiment of the present application.

FIG. 3b is a schematic plan view showing an evaporation system formed as a linear evaporation source according to an embodiment of the present application.

FIG. 3c is a schematic plan view showing an evaporation system formed as an area evaporation source according to an embodiment of the present application.

FIG. 4a is a schematic perspective view showing an evaporation system according to an embodiment of the present application, where the evaporation system includes a crucible, a moving device for the crucible, and a control device.

FIG. 4b is a schematic perspective view showing an evaporation system according to an embodiment of the present application, where the evaporation system includes a plurality of crucibles arranged into a linear evaporation source, a plurality of moving devices for the plurality of crucibles, and a general control device.

FIG. 4c is a schematic perspective view showing an evaporation system according to an embodiment of the present application, where the evaporation system includes a plurality of crucibles arranged into an area evaporation source, a plurality of moving devices for the plurality of crucibles, and a general control device.

FIG. 5 is a block diagram of an evaporation system according to an embodiment of the present application.

### DETAILED DESCRIPTION OF PREFERRED EMBODIMENTS

Many specific details are set forth hereinafter in the following description to provide an overall understanding of the embodiments of the present application. Obviously, however, one or more embodiments can be implemented without these details. Well-known structures and devices are omitted to simplify the drawings, and similar reference numerals are used to indicate similar components throughout the drawings.

It is noted that, term “include” or “comprise” should not be construed as excluding any other elements or steps, and terms “a” or “an” should not be construed as excluding “more than one”. Moreover, reference numerals should not be construed as a limitation to the scope of the invention.

FIG. 2 is a schematic drawing showing a structure of an evaporation system including a plurality of crucibles according to an embodiment of the present application. The evaporation system includes a plurality of regularly arranged crucibles 10, and the plurality of crucibles 10 as a whole are used to coat an objective substrate, such as an OLED substrate. The plurality of crucibles 10 may be arranged in accordance with a shape of a substrate to be coated.

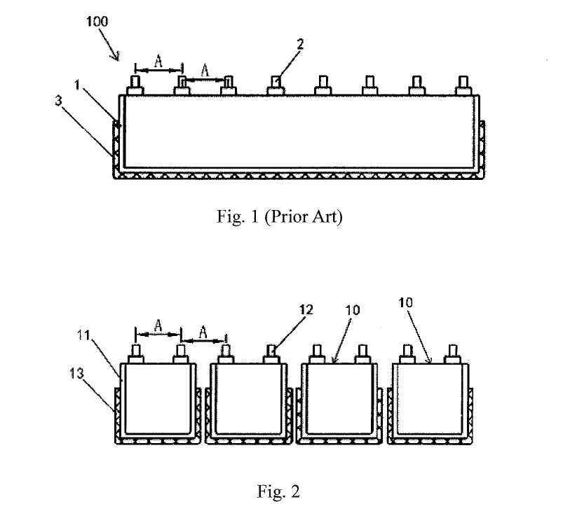

The plurality of crucibles 10 of the evaporation system shown in FIG. 2 may replace the crucible 100 of FIG. 1 having corresponding sizes, to coat an objective substrate. As compared with the crucible 100 shown in FIG. 1, the evaporation system shown in FIG. 2 utilizes a plurality of small sized independent crucibles 10, each small sized crucible 10 is separately heated by a heating device 13 disposed externally to the crucible body, each crucible 10 is heated to the same extent, and a distance between nozzles of adjacent crucibles of the evaporation system is also set to A. Thus, the evaporation system shown in FIG. 2 may overcome the defect of insufficient evaporation of central vapor deposition material which cannot be sufficiently heated due to the large sized crucible 100 shown in FIG. 1, and thereby may improve uniformity of the coating of the substrate.

According to an embodiment of the present application, each crucible 10 of the evaporation system of FIG. 2 may include a crucible body 11 and at least one nozzle 12 disposed at the top of the crucible body, and the crucible body 11 may include an inner wall and an outer wall that are bonded together. The inner wall is made of a first material, the outer wall is made of a second material, and a heat conductivity of the first material is larger than that of the second material.

Specifically, the outer wall may be formed of Ti, and the inner wall may be formed of a material selected from a group consisted of copper (Cu), argentine (Ag), aluminum (Al) and a combination thereof. Thus, the outer wall formed of Ti may meet strength requirement of a crucible, such that the crucible would not be deformed under high temperature; the inner wall formed of Cu, Ag, Al or other materials having good thermal conductivity may ensure heat being swiftly transferred, such that heat may be transferred quickly from one region to another to ensure temperature uniformity of the entire inner wall of the crucible, and vapor deposition material contacting the inner wall may be evaporated uniformly. However, the material of the inner wall should not react with the vapor deposition material.

In FIG. 2, each crucible 10 has two nozzles. In another embodiment, each crucible 10 may only has one nozzle. When the number of nozzle is relatively small, each crucible 10 may have relatively small sizes to prevent the vapor deposition material inside a single crucible from being heated non-uniformly.

Further, although plurality of crucibles 10 may form an evaporation system, as shown in FIG. 2, each crucible 10 may be used separately if the substrate has small sizes. For example, when manufacturing a small sized display panel for a portable device such as mobile phone, a single crucible may be used to perform vapor deposition.

According to an embodiment, the crucible 10 may have a rectangular shape, sizes of the crucible may be in a range from 100×100×200 (mm) to 150×100×250 (mm) in a form of length×width×height. Or, the crucible may have relatively small sizes to be adapted for manufacturing of a mobile phone or another device that has a relatively small display device. A crucible having relative small sizes may prevent vapor deposition material at a central region inside the crucible from being insufficiently heated, and prevent defects in coatings due to non-uniformity of material evaporation.

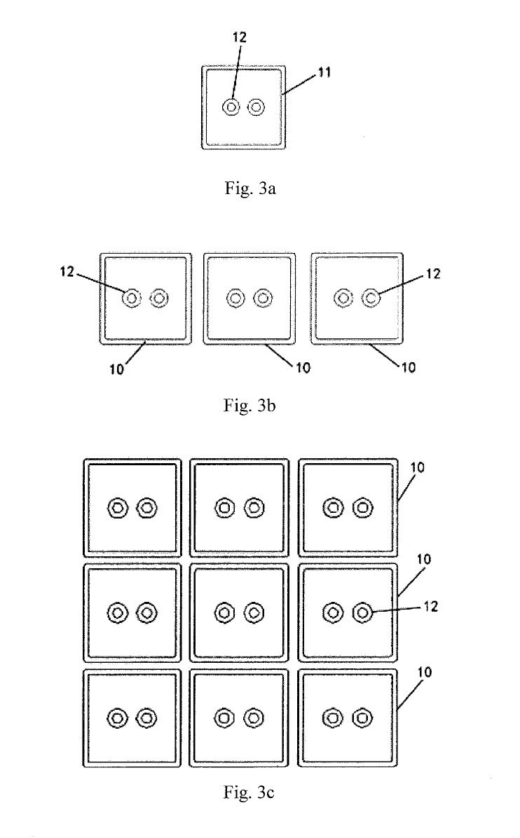

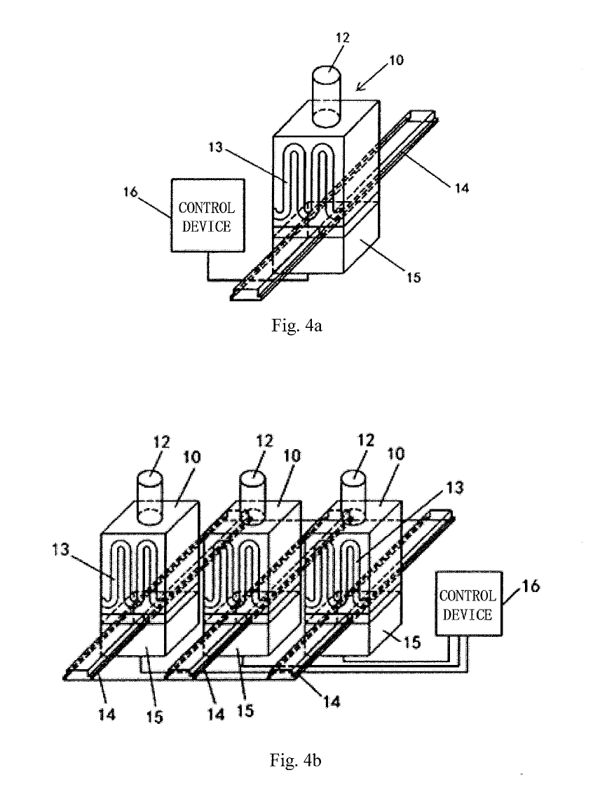

When a computer monitor, a TV set or the like that has a relative large display device is to be manufactured, the evaporation system composed of the plurality of crucibles 10 as shown in FIG. 2 may be utilized. In the evaporation system, the plurality of crucibles 10 are uniformly arranged into a linear evaporation source (FIG. 3b) or an area evaporation source (FIG. 3c). In the condition of the plurality of crucibles 10 being arranged into a linear evaporation source, nozzles 12 of the plurality of crucibles 10 are arranged equidistantly (FIG. 2), such that vapor deposition material may be evaporated uniformly across the entire evaporation system, and a uniform coating may be formed.

FIG. 3a is a schematic plan view showing an evaporation crucible forming a spot evaporation source according to an embodiment of the present application. FIG. 3b is a schematic plan view showing an evaporation system formed as a linear evaporation source according to an embodiment of the present application. FIG. 3c is a schematic plan view showing an evaporation system formed as an area evaporation source according to an embodiment of the present application. In practice, the plurality of evaporation crucibles may be arranged into a linear or area evaporation source having various sizes according to practical requirements, such that it may be flexibly adapted for coating all kinds of substrates. Further, the number of the nozzles and positions of the nozzles on the top surface of the crucible body may be set according to practice requirements, and spacing between adjacent nozzles may be adjusted according to practice requirements such that spacings between any two adjacent nozzles are the same.

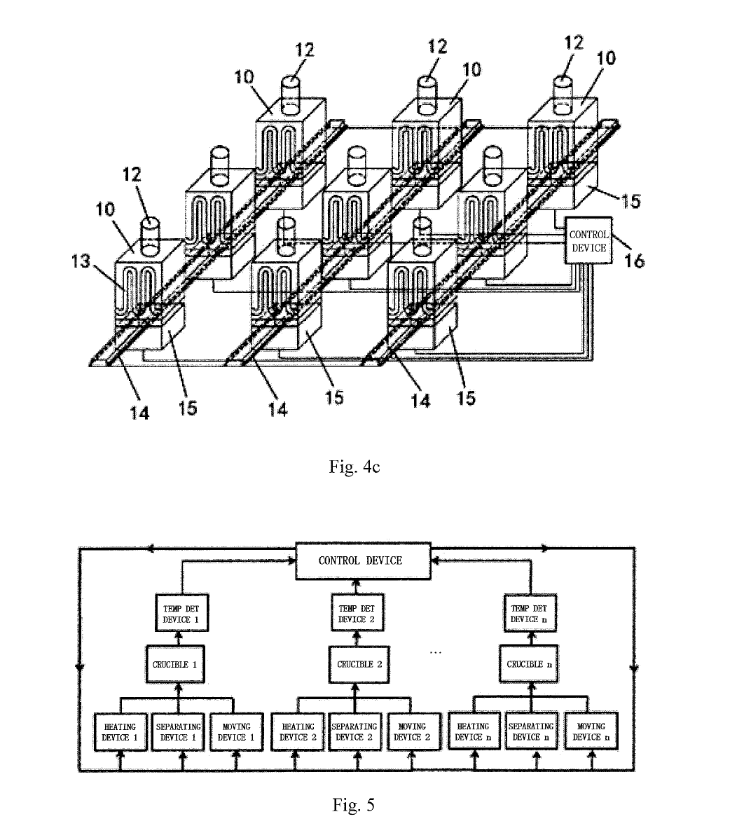

In order to facilitate adjusting the position of each crucible 10 to form a predetermined crucible pattern, according to a further embodiment of the present application, the evaporation system may further include a plurality of crucible moving device for moving corresponding crucibles 10 respectively and independently. FIG. 4a is a schematic perspective view showing an evaporation system according to an embodiment of the present application, where the evaporation system includes a crucible, a moving device for the crucible, and a control device. FIG. 4b is a schematic perspective view showing an evaporation system according to an embodiment of the present application, where the evaporation system includes a plurality of (3 as shown in the figure) crucibles arranged into a linear evaporation source, a plurality of moving devices for the plurality of crucibles, and a general control device. FIG. 4c is a schematic perspective view showing an evaporation system according to an embodiment of the present application, where the evaporation system includes a plurality of (9 as shown in the figure) crucibles arranged into an area evaporation source, a plurality of moving devices for the plurality of crucibles, and a general control device.

As shown in FIGS. 4a to 4c, each crucible 10 is provided with a moving device, which includes a guiding rail 14 and a servo motor 15. The servo motor 15 drives the corresponding crucible 10 to move on the guiding rail 14. Thus, according to the embodiment, each crucible may be conveniently moved as desired to form a predetermined linear or area evaporation source. Further, each servo motor 15 is connected to a control device 16 (such as a personal computer) via a conductor, such that each servo motor 15 may be driven or controlled by the control device 16.

FIG. 5 is a block diagram of an evaporation system according to an embodiment of the present application. As shown in FIG. 5, an evaporation system according to an embodiment of the invention may include one to n crucibles, and each crucible is provided with a heating device, a crucible moving device, a separating device for separating the heating device from the crucible, and a temperature detecting device.

To be noted, in the embodiments shown in FIGS. 3a and 4a, for example, since a single crucible is used separately, the heating device 13 may be configured as a part of the crucible. While a plurality of crucibles form an evaporation system and one of the crucibles may be operated separately, thus, the heating device 13 and the crucible 10 may be formed as different components.

The entire evaporation system is provided with a control device. A heating device is used to heat a corresponding crucible to evaporate vapor deposition material inside the crucible. A crucible moving device, which may for example include the guiding rail and the servo motor shown in FIGS. 4a-4c, is used to move a corresponding crucible. A separating device is used to control a corresponding heating device and a corresponding crucible to move close to or away from each other, such that heating of each crucible may be controlled separately. Each temperature detecting device is used to measure a temperature of a corresponding crucible, such that heating or cooling of the crucible may be controlled based on the temperature of the crucible. The control device is configured to be associated with the moving device, the heating device, the separating device and the temperature detecting device to control operations of the moving device, the heating device, the separating device and the temperature detecting device, so as to realize an automatic control of the evaporation system.

Specifically, when the temperature detecting device knows that a temperature of a certain crucible is too high through measuring, it can send a temperature signal to the control device, then the control device may control the separating device to separate the heating device (for example, a heating wire) from the crucible, so as to realize the temperature control. Further, the control device may additionally or alternatively control every heating device based on temperature signals input by corresponding temperature detecting devices, and in such a manner, the crucibles may be heated separately, temperatures of the crucibles may be controlled separately, and consistency of the temperatures of all the crucibles may be ensured. Since the evaporation system utilizes a plurality of small crucibles, and a small crucible has advantages of fast heating speed, high heat conductivity, uniform heating, and inner wall of the crucible is formed of materials having high heat conductivity, such as Cu, Ag or the like, heat may be quickly transferred to vapor deposition material, such that temperature uniformity of evaporation can be ensured, and rate of vapor deposition may be controlled conveniently.

The above embodiments are described only to exemplarily set forth the concept and mechanism of the present application, however, the invention is not limited thereto. An ordinary skilled in the art would appreciate that any changes or modification made to the present invention without departing from the concept of the invention shall fall within the scope of the invention, which should be defined by the appended claims and their equivalents.

1. An evaporation crucible, comprising:
a crucible body; and
at least one nozzle located on a top face of the crucible body,
wherein the crucible body comprises an inner wall and an outer wall that are bonded together, the inner wall is formed of a first material, the outer wall is made of a second material, and a heat conductivity of the first material is larger than that of the second material.

2. The evaporation crucible according to claim 1, wherein the outer wall is formed of Ti, the inner wall is formed of a material selected from a group consisted of Cu, Ag, Al and a combination thereof.

3. The evaporation crucible according to claim 1, wherein the evaporation crucible comprises one or two nozzles.

4. The evaporation crucible according to claim 1, wherein the evaporation crucible further comprises a heating device disposed externally to the crucible body, for heating the crucible.

5. An evaporation system for performing vapor deposition on an objective substrate, comprising a plurality of crucibles arranged into a certain pattern, wherein each crucible is the evaporation crucible according to claim 1.

6. The evaporation system according to claim 5, wherein the plurality of crucibles are arranged such that spacings between any two adjacent nozzles are the same.

7. The evaporation system according to claim 5, wherein the plurality of crucibles are arranged into a linear evaporation source.

8. The evaporation system according to claim 5, wherein the plurality of crucibles are arranged into an area evaporation source.

9. The evaporation system according to claim 5, wherein the evaporation system further comprises a plurality of crucible moving device for moving the plurality of crucibles respectively and independently.

10. The evaporation system according to claim 9, wherein each crucible moving device comprises a guiding rail and a servo motor for driving a corresponding crucible to move on the guiding rail.

11. The evaporation system according to claim 9, wherein each crucible is provided with a heating device.

12. The evaporation system according to claim 11, wherein each crucible is provided with a separating device for controlling a corresponding heating device to move close to or away from the crucible.

13. The evaporation system according to claim 12, wherein each crucible is provided with a temperature detecting device for measuring a temperature of the crucible.

14. The evaporation system according to claim 13, wherein the evaporation system further comprises a control device associated with the moving device, the heating device, the separating device and the temperature detecting device, for controlling operations of the moving device, the heating device, the separating device and the temperature detecting device.

15. The evaporation system according to claim 5, wherein the outer wall is formed of Ti, the inner wall is formed of a material selected from a group consisted of Cu, Ag, Al and a combination thereof.

16. The evaporation system according to claim 5, wherein each evaporation crucible comprises one or two nozzles.
